(19) United States
(12) Patent Application Publication
(10) Pub. No.: US 2010/0316554 A1
(43) Pub. Date: Dec. 16, 2010

(54) METHOD FOR THE MANUFACTURE OF NANOPARTICLES ON A CARBON SURFACE AND PRODUCTS THEREFROM

(75) Inventors: Beatriz Hernandez, Madrid (ES); Horst Weller, Hamburg (DE); Christian Klinke, Hamburg (DE); Mona Nagel, Aalen (DE); Andreas Kornowski, Hasloh (DE)

Correspondence Address: INTELLECTUAL PROPERTY / TECHNOLOGY LAW, PO BOX 14329, RESEARCH TRIANGLE PARK, NC, 27709, US

(73) Assignee: CENTRUM FUR ANGEWANDTE NANOTECHNOLOGIE (CAN) GMBH, Hamburg (DE)

(21) Appl. No.: 12/593,312

(22) PCT Filed: Mar. 28, 2008
(86) PCT No.: PCT/EP2008/002482

§ 371 Date: Mar. 29, 2010

(30) Foreign Application Priority Data
Mar. 28, 2007 (GB) 0706128.6

(51) Int. Cl. C01B 31/00

(52) U.S. Cl. 423/414; 977/748; 977/939; 977/950

(57) ABSTRACT

The combination of at least one substantially unfunctionalised carbon surface, such as a fullerene, graphite or amorphous carbon, graphene or pre-aligned carbon nanotubes and at least semi-conducting nanoparticle, for example CdSe, CdTe, CdS, InP and/or ZnO or a metallic alloy nanoparticle is described wherein the at least one nanoparticle is directly attached to the substantially unfunctionalised carbon surface. A method for the manufacture of the nanoparticles is also described. This method comprises: —dissolving a cation source in a first organic solvent to produce a cation-containing medium; —adding a plurality of substantially unfunctionalised carbon surfaces to the cation-containing medium to form a cation-carbon mixture; —adding an anion-containing medium to the mixture of the cation-containing medium and carbon surfaces to form a cation-carbon-anion mixture, In the case of alloy nanoparticles, another cation medium is added instead. —leaving the cation-carbon-anion mixture at a temperature of between 60° C. and 300° C. between 10 minutes and 1 week, depending on the system.

### SUMMARY OF THE INVENTION

The invention relates to a combination of a carbon surface, for example a fullerene, graphene, graphite or amorphous carbon, and at least one nanoparticle (NP), such as a II-VI, III-V semi-conductor or at least one metallic alloy nanoparticle such as CoₓPt_{y}, NiₓPt_{y} or FeₓPt_{y}. The invention furthermore relates to a method of manufacturing such nanoparticles (NPs) and their use in electronic devices, including photovoltaic cells and light emitting diodes.

### INTRODUCTION

There is an increasing number of potential applications for materials with dimensions in the nanometer range (i.e. between 1 nm and 100 nm). Such so-called nano-systems show improved or even new properties as a result of electronic confinement with the nano-systems. In particular, carbon nanotubes (CNTs) find applications as transistors (see P. Avouris, Acc. Chem. Res. 35, 1026 (2002). and H. Dai, Surf Sci. 500, 218 (2002).), conductive layers (E. Artukovic, M. Kaempgen, D. S. Hecht, S. Roth, G. Grüner, Nano Lett. 5, 757 (2005)), field emitters (J. M. Bonard, K. A. Dean, B. F. Coll, C. Klinke, Phys. Rev. Lett. 89, 197602 (2002) and N. de Jonge, Y. Lamy, K. Schoots, T. H. Oosterkamp, Nature 420, 393 (2002).) and mechanical components (A. K is, G. Csanyi, J. P. Salvetat, T. N. Lee, E. Couteau, A. J. Kulik, W. Benoit, J. Brugger, L. Forro, Nature Mat. 3, 153 (2004), J. Cumings, A. Zettl, Science 289, 602 (2000). and I. Palaci, S. Fedrigo, H. Brune, C. Klinke, M. Chen, E. Riedo, Phys. Rev. Lett. 94, 175502 (2005)). Significant progress has also been made in controlling some other carbon based nanostructures such as graphene (see A. K. Geim and K. S. Novoselov, Nature Materials 6, 183, (2007) or Vazquez de Parga, A. L et al., Physical Review Letters, 2008, 100, 056807).

Knowledge acquired from well-established methods of manufacturing has facilitated tailoring and optimization of semi-conductor nanoparticles with efficient, photostable luminescence properties controlled by quantization. Reports have been published, for example, in Z. Adam Peng and Xiaogang Peng, J. Am. Chem. Soc. 2001, 123, 183-184; Z.

Adam Peng and Xiaogang Peng, J. Am. Chem. Soc. 2001, 123, 1389-1395; Talapin D V et al. Nano Letters 3 (12): 1677-1681 2003; Talapin D V, Rogach A L, Kornowski A, et al. Nao Letters 1 (4): 207-211 APR 2001; Liberato Manna, Erik C. Scher, and A. Paul Alivisatos, J. Am. Chem. Soc. 2000, 122, 12700-12706; Xiaogang Peng et al. Nature 404, 2000; T. Mokari et al. Nature Materials, 4, 5, 855, (2005);

Control of size and shape of the nanoparticles has been achieved during the last decades for some specific systems such as CdSe (see, for example, Z. Adam Peng and Xiaogang Peng, J. Am. Chem. Soc. 2001, 123, 183-184; Z. Adam Peng and Xiaogang Peng, J. Am. Chem. Soc. 2001, 123, 1389-1395; Talapin D V et al. Nano Letters 3 (12): 1677-1681 December 2003; Talapin D V, Rogach A L, Kornowski A, et al. Nano Letters 1 (4): 207-211 APR 2001) or PbS (see Moffit M, Eisenberg A, Chem. Mater 7 (6): 1178-1184 June 1995; Cademartiri L, et al. J. Phys. Chem. B 110 (2): 671-673 January 19 2006; J. Joo, H. B. Na, T. Yu, J. H. Yu, Y. W. Kim, F. Wu, J. Z. Zhang, T. Hyeon, J. Am. Chem. Soc. 125 (2003) 11100.).

There is furthermore a strong interest to attach NPs to one-dimensional systems such as CNTs. For example, it is known that metallic particles can serve as catalysts to create branches on nanotubes, (C. Klinke, E. Delvigne, J. V. Barth, K. Kern, J. Phys. Chem. B 109, 21677 (2005) while semi-conducting NPs can act as light absorbing sites to increase the photoconductivity of CNTs (Wei Feng et al. J. Phys.: Condens. Matter 17 (2005) 4361-4368) as further exemplified in Robel, I., B. A. Bunker, and P. V. Kamat, Advanced Materials, 2005. 17(20): p. 2458.

Metallic nanoparticles on carbon nanotubes are potentially interesting for the following applications: Electrocatalytic Activity for Oxygen Reduction Reaction: Kongkanand et al., Langmuir 22, 2392, (2006), proton Exchange Membrane Fuel Cells: Liu et al., Langmuir 18 4054, (2002), catalysts, hydrogenstorage, controlled electronic contacts: Wildgoose et al., Small 2, 182, (2006) or catalysts for direct methanol fuel cell: Wang et al., Electrochimica Acta 52 (2007) 7042-7050. Carbon nanotubes and magnetic nanostructures attact interest in Spintronics: Nature 445, 410, 2007; Diamond and Related materials 13, 215, (2004)

In previous studies, semi-conductor NPs have been grown on CNTs by generation of defects in the CNT lattice structure by means of covalent functionalisation (S. Banerjee and S. S. Wong, J. Am. Chem. Soc. 125, 10342, (2003); S. Ravindran, S. Chaudhary, B. Colburn, M. Ozkan, C. S. Ozkan, Nano Letters, 3, 4, 447, (2003) or ozonolysis (S. Banerjee and S. S. Wong, Chem. Comm, 1866, (2004). These aggressive treatments render a functionalised CNT surface which deteriorates the response of the CNTs in terms of conductivity and optical behaviour (R. G. Compton, C. E. Banks, G. G. Wildgoose, Small 2, 2, (2006)). The aggressive treatments may also lead to structural damage in the CNT which is a disadvantage for further applications (C. Klinke, J. B. Hannon, A. Afzali, P. Avouris, Nano Lett. 6, 906 (2006).

US Patent Application No US 2006/0024503 teaches one method of manufacturing the semi-conductors NP which are described in the patent application as being “fused” to the CNTs by means of a covalent bond. In this '503 patent application a mixture of CNTs is oxidized or hydrolyzed at temperatures between 100° C. and 400° C. before the temperature of the CNT mixture is lowered to about 70° C. and the solid state NPs are allowed to form on the surface of the CNTs. The effect of the oxidization is to produce oxygen moieties on the surface of the CNT to provide nucleation sites. The '503 patent application notes that there is a large variation of the shapes of the NPs formed by the method disclosed in the patent application. The shape of the NPs is controlled by the spatial location and the distribution of the oxygen moieties on the surfaces of the NPs.

However, there are a few examples where composites of CNTs and NPs can be obtained under mild conditions providing an attachment based on electrostatic interactions (S. Gorer, J. A. Ganske, J. C. Hemminger, R. M. Penner, J. Am. Chem. Soc. 120, 9584 (1998) and S. Chaudhary, J. H. Kim, K. V. Singh, M. Ozkan, Nano Lett. 4, 2415 (2004)). Recently, CdSe nanoparticles and InP nanoparticles have been attached to single-wall carbon nanotubes (SWCNTs) (C. Engtrakul, Y. H. Kim, J. M. Nedeljkovic, S. P. Ahrenkiel, K. E. H. Gilbert, J. L. Alleman, S. B. Zhang, O. I. Micic, A. J. Nozik, M. J. Heben, J. Phys. Chem. B (2006)). After incubation at low temperature (70° C.) the CdSe nanoparticles and InP nanoparticles nest mainly in bundled CNTs due to favourable energetic conditions.

The method for the manufacture of the composites in the work by Engrakul et al. comprises several steps. Firstly the synthesis of single-wall carbon nanotubes by laser vaporisation followed by purification in a two-step purification process. The purified SWCNT was dispersed in toluene (3 mg/3 ml) by sonication for 5 min and stirred for 18 h at 80° C. under nitrogen. Secondly, the InP and CdSe nanoparticles were synthesised separately from the synthesis of the carbon nanotubes and stabilised in a trioctylphosphine/trioctylphosphine oxide (TOP/TOPO). Finally, a 2 ml aliquot of TOP/TOPO capped InP or CdSe QDs in hexanes (with an Optical Density of 0.5) was added to the suspended SWCNTs, and stirring was continued for an additional 18 hours at 80° C. under nitrogen. The nanoparticles were bound to the surface of the carbon nanotubes by van der Waal's forces.

Engrakul et al. report that the tendency to form linear arrays of the nanoparticles was greatest when alignment between the carbon nanotubes was relatively good within bundles. This is due to the fact that the nanoparticles nest in the grooves between the carbon nanotubes which form when the carbon nanotubes bundle. The edge-to-edge (ee) separation distance between nanoparticles in the 1-D arrays of the Engrakul paper was 18 Å for both the InP and the CdSe nanoparticles. This separation distance indicates that nanoparticle-nanoparticle separation is governed by the thickness of ligand shells, as is the case in two and three-dimensional nanoparticle arrays. The ligands are organic molecules, for example, ODPA and TOPO that cover the nanoparticles as separators between the nanoparticles and also between the carbon nanotubes surface and the nanoparticles.

Other patent applications are known in which CNTs are attached to a NP. For example, US Patent Application Publication No US 2005/0045867 (Ozkan et al.) teaches a heterojunction with at least one carbon nanotube to which a nanostructure, preferably a quantum dot such as a ZnS capped CdSe core, is attached. The method of manufacture taught in the '867 patent application is the oxidation of the ends of the CNT, placing at least one amine group on the oxygen moieties and then coupling the end of the CNT with the nanostructure. The resulting heterojunctions can be employed in the manufacture of electronics and optoelectronics devices such as LEDs, single-electron transistors, spintronic devices, flat panel displays, vacuum microelectronics sources, biosensors, RAMs, spin valves and other devices.

US Patent Application Publication No US 2007/0292699 discloses a process for depositing nanometre-sized metal particles onto a carbon substrate in the absence of aqueous solvent, organic solvents and reducing agents, and without any pre-treatment of the substrate. The process includes preparing an admixture of a metal compound and a substrate by dry mixing a chosen amount of metal compound with a chosen amount of substrate; and supplying energy to the admixture in an amount sufficient to deposit zero valence metal particles onto the carbon substrate

US Patent Application Publication No US 2005/0157445 (Bradley et al.) teaches the electro deposition of NPs onto the surface of a CNT.

U.S. Pat. No. 6,987,302 teaches a nanotube with a magnetic nanoparticle attached to the exterior sidewall of a CNT. The surface of the CNT is activated to generate various functional groups and the attachment of the magnetic NPs is achieved by electrostatic interactions, via polyelectrolyte, or by hydrophobic interchain interactions between the functional groups on the CNT with a molecular chain on the coating of the magnetic NP.

PCT Patent Application No WO 2005/069412 (KH Chemicals) teaches the use of sulphur or metal NPs as a binder between CNTs.

Korean Patent Application KR 2004-0079226 teaches the coating of a transition metal oxide on a CNT by CVD or physical deposition.

### SUMMARY OF THE INVENTION

A novel approach to the manufacture of semi-conductor nanoparticles or metallic alloy nanoparticles such as COₓPt_{y}, NiₓPt_{y} or FeₓPt_{y} and their attachment to unfunctionalized carbon surface is disclosed. In this invention the carbon surface is neither previously treated nor functionalized prior to the manufacture of the NPs. The attachment of the NP or metallic alloy nanoparticle such as CoₓPt_{y}, NiₓPt_{y} or FeₓPt_{y} is observable in single-wall (SWCNTs), multi-wall carbon nanotubes (MWCNTs), pre-aligned CNTs, as well as graphene, graphite and amorphous carbon. In addition, this approach yields a morphological transformation of CdSe NPs. Semi-conductor CdSe NPs that, in a first stage grow as rods, undergo a shape transformation in the presence of unfunctionalised CNTs are one non-limiting example of the invention.

The invention provides for at least one substantially unfunctionalised carbon surface and at least one semi-conducting nanoparticle or at least one metallic alloy nanoparticle such as COₓPt_{y}, NiₓPt_{y} or FeₓPt_{y}. The nanoparticle is directly attached (i.e. without the presence of ligands) to the carbon surface. Unlike the previous prior art, the invention does not require the carbon surface to be functionalized to provide functional groups as nucleation sites, such as oxygen moieties, to which the nanoparticle is attached. This means that the method of manufacture is substantially simplified as there is no need for a processing step to functionalize the carbon surface. Furthermore there are no ligands between the carbon surface and the nanoparticle. The bonding between the semi-conducting nanoparticle and the carbon surface is by coordinative bonds. In the case of metallic alloy nanoparticles, the interaction between the carbon surface and metallic alloy nanoparticle (such as CoₓPt_{y}, NiₓPt_{y} or FeₓPt_{y}) is an electrostatic interaction.

The shape of the nanoparticle is substantially pyramidal-shaped in the case of CdSe or ZnO nanoparticles. The nanoparticles grow in solution and then the nanoparticles are transformed over time in one aspect of the invention to form the pyramidal-shaped upon interaction with the unfunctionalised carbon as will be discussed in the body of the specification. Then the nanoparticle-carbon surface composite is obtained in situ. In this context pyramidal shape means a polyhedral structure with a hexagonal base (or bullet shape). It has been found that the invention allows the morphology of the nanoparticles to be changed so that the nanoparticles take a uniform shape, rather than having a multitude of different shapes.

The invention provides for the manufacture of a substantially greater number of nanoparticles compared to the prior art methods. For example at least 40% of the surface area of the carbon surface is coated with the plurality of the nanoparticles; whereas the published photographs of the prior art methods indicate that a much lower proportion of the area of the carbon surface is coated with the nanoparticles. (See for Example S. Banerjee and S. S. Wong, J. Am. Chem. Soc. 125, 10342, (2003).

It has been found that the carbon surface is preferably selected from the group of allotropes of carbon consisting of graphite, amorphous carbon, fullerenes and graphene. Fullerenes are interesting structures which are finding wide application in the manufacture of electronic devices, such as photovoltaic devices. Most preferably the carbon surface is a multi-wall carbon nanotube, a single-wall carbon nanotubes or a pre-aligned carbon nanotube, but the invention is not limited in any way to carbon nanotubes (i.e., double-wall). It is known that multi-wall carbon nanotubes are metallic in nature and therefore they are capable of driving higher current densities and are thus suitable for photovoltaic devices. Single-wall carbon nanotubes have fewer defects in their structure and are therefore particularly suitable when the electronic device requires only a single nanotube.

The invention also provides a method for the manufacture of nanoparticles comprising:

dissolving a cation source in a first organic solvent to produce a cation-containing medium;

adding a plurality of substantially unfunctionalised carbon surfaces to the cation-containing medium to form a cation-carbon mixture;
adding an anion-containing medium to the mixture of the cation-containing medium and carbon surfaces to form a cation-carbon-anion mixture; In the case of the metal alloy nanoparticles, a second cationic source is added.

leaving the above described mixture at a temperature of between 60° C. and 300° C. between 10 minutes and 1 week, depending on the reaction system). This method has a number of advantages over the known prior art methods as it allows a simple but reliable method for the manufacture of the nanoparticles which avoids the use of a functionalisation step as is known in the prior art. It is, for example, required to manufacture nanoparticles and carbon nanotubes in two separate steps and then mix together, as is known in the prior art.

The method can also be used to produce uniformly shaped nanoparticles which are substantially pyramidal-shaped or modify existing nanoparticles such that the nanoparticles form substantially pyramidal shapes. Prior art nanoparticles had a variety of shapes.

### DESCRIPTION OF THE FIGURES

FIG. 1 shows CdSe particles obtained after 48 hours (a) in absence and (b) in the presence of MWCNTs

FIG. 2 shows the synthesized CdSe nanoparticles in the presence of 0.6 mg of SWCNT after (a) 20 hours and (b) 60 hours.

FIG. 3 shows the Raman response of pure SWCNTs, SWCNTs treated in a mixture ODPA/TOPO at 245° C. and that of the sample shown in FIG. 2b.

FIG. 4 shows the optical absorption spectra for pure SWCNTs, SWCNTs treated in a mixture ODPA/TOPO at 245° C. and that of the sample shown in FIG. 2 (the spectra are shifted vertically for clarity).

FIG. 5 shows the proposed mechanism for the interaction and morphological transformation of CdSe nanorods in the presence of CNTs. Upon (a) CdSe-CNTs interaction, (b) selective etching, (c) selective etching and Ostwald Ripening processes lead to the situation (d) with examples shown in FIGS. 1b and 2b.

FIG. 6 shows the ZnO nanoparticles obtained in the presence of SWCNTs with different alcohols as solvent, The top figure shows in methanol at 60° C. and the lower in 2-phenyl ethanol at 200° C. after three days of reaction.

FIG. 7 shows the ZnO nanoparticles with addition of oleic acid to the synthesis in phenyl ethanol at 200° C. after one day of reaction (Zn(Ac)₂:OA, 1:1). The top figure shows synthesis in the presence of SWCNTs and the lower figure in the presence of MWCNTs.

FIG. 8 show the InP nanoparticles obtained in the presence of SWCNTs.

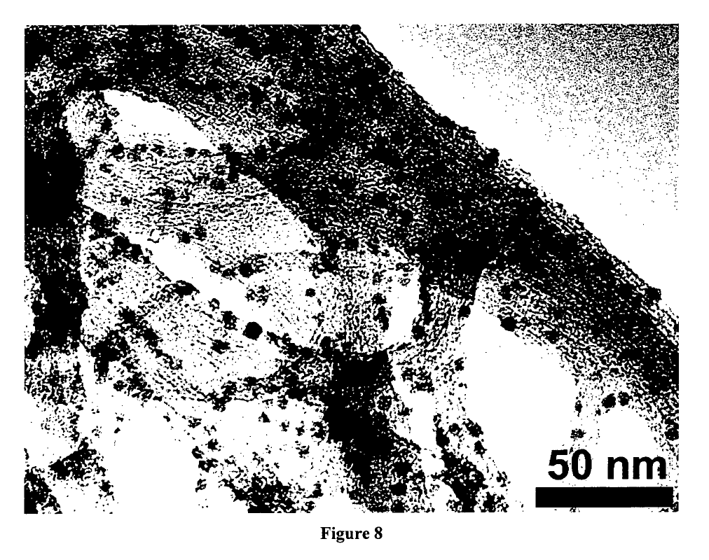

FIG. 9 shows, above CoPt nanoparticles obtained by using CO₂(CO)₈ as a Co precursor and below using CoCl₂.6H₂O as a Co precursor. In the above Figure the nanoparticles are Pt rich while in the lower Figure they have stoichiometry 1:3.

FIG. 10 shows NiPt nanoparticles attached to MWCNTs.

### DETAILED DESCRIPTION OF THE INVENTION

The invention is a novel approach to attach semi-conductor NPs or metallic alloy nanoparticles (with controlled stoichiometry) to unfunctionalised carbon. The semi-conductor particles include, but are not limited to, CdSe, CdTe, CdS, InP, and ZnO.

The unfunctionalised carbon can be allotropes of carbon such as fullerenes (including carbon nanotubes and pre-aligned carbon nanotubes, buckminsterfullerene-(C60-Ih)[5,6]fullerene, graphite, graphene and amorphous carbon. The carbon nanotubes can be single-wall carbon nanotubes and multi-wall carbon nanotubes. A number of prior art methods are known for the manufacture of the unfunctionalised carbon; such products can also be commercially purchased.

The term “unfunctionalised” or “non-functionalised” means that the surface of the carbon has not been treated to produce functional groups as nucleation sites. It should be noted that the surface may have a small number of defects which occur during the manufacture of the carbon. However, this small number of defects does not account for the number of nanoparticles formed on the surface of the carbon in accordance with this invention and therefore the carbon surface can be considered to be unfunctionalised.

The term “unfunctionalised” also means that the surface of the carbon has not been modified by means of any procedure involving covalent bonding or non-covalent bonding of a molecule, functional group, ion or other chemical moiety.

Covalent functionalisation includes addition reactions to the surface of the carbon and oxidation of the surface of the carbon. The oxidation results in carboxyl groups at the ends of the carbon nanotube and other high defect density sites on the surface of the carbon

The oxidation of the surface of the carbon can be carried out by oxygen plasma treatment, thermal oxidation, ozonolysis or liquid phase oxidation with acids. Some other covalent functionalisation procedures involve amide bond formation at the nanotube ends using carboxylate groups (S. S. Wong, E. Joselevich, A. T. Woolley, C. L. Cheung, C. M. Lieber, Nature 1998, 394, 52).

The sidewalls of the carbon nanotube can also be non-selectively attacked by highly reactive species such as carbenes, (Y. Chen, R. C. Haddon, S. Fang, A. M. Rao, P. C. Eklund, W. H. Lee, E. C. Dickey, E. A. Grulke, J. C. Pendergrass, A. Chavan, B. E. Haley, R. E. Smalley, J. Mater. Res. 1998, 13, 2423) azomethine ylides (V. Georgakilas, K. Kordatos, M. Prato, D. M. Guldi, M. Holzinger, A. Hirsch, J. Am. Chem. Soc. 2002, 124, 760) and aryl diazonium salts (J. L. Bahr, J. Yang, D. V. Kosynkin, M. J. Bronikowski, R. E. Smalley, J. M. Tour, J. Am. Chem. Soc. 2001, 123, 6536) or may be modified via [4+2]cycloaddition reactions (G. Sakellariou et al. Chem. Mater., 19, 6370, 2007).

Non-covalent functionalisation covers a broad range of terms from weak physisorption to strong coordinative or ionic binding. While the non-covalent bonding to the carbon nanotube leaves the sp²-bonded carbon framework of the carbon nanotubes generally intact, a charge transfer from the surface of the carbon nanotube to the bound chemical moiety can occur if. the adsorbed chemical moieties have sufficient electron-donating or electron-accepting capability.

The non-covalent functionalisation also includes binding of atomic or molecular gases (A. Kuznetsova, D. B. Mawhinney, V. Naumenko, J. T. Yates, J. Liu, R. E. Smalley, Chem. Phys. Lett. 321 (2000) 292-296; A. Fujiwara, K. Ishii, H. Suematsu, H. Kataura, Y. Maniwa, S. Suzuki, Y. Achiba, Chem. Phys. Lett. 336 (2001) 205-211), organic molecules (J. Kong, H. J. Dai, J. Phys. Chem. B 105 (2001) 2890-2893, including aromatic organic molecules (R. J. Chen, Y. G. Zhan, D. W. Wang, H. J. Dai, J. Am. Chem. Soc. 123 (2001) 3838-3839) polymers (M. J. O'Connell, P. Boul, L. M. Ericson, C. Huffman, Y. H. Wang, E. Haroz, C. Kuper, J. Tour, K. D. Ausman, R. E. Smalley, Chem. Phys. Lett. 342 (2001) 265-271, M. Shim, A. Javey, N. W. S. Kam, H. J. Dai, J. Am. Chem. Soc. 123 (2001) 11512-11513) or ionic species (J. Zhao, A. Buldum, J. Han, J. P. Lu, Phys. Rev. Lett. 85 (2000) 1706-1709; T. Pichler, A. Kukovecz, H. Kuzmany, H. Kataura, Synth. Met. 135 (2003) 717-719).

Ionic doping can be considered as a special case of non-covalent functionalisation defined by the existence of pronounced charge transfer between the nanotubes and the absorbed atoms or molecules.

The composites of the nanoparticles and the carbon made in accordance with the current invention can be used for electronic devices, such as photoconductive structures. The photoconductive structures can be used in the development of highly efficient solar cells. For example, the CdSe nanoparticles can efficiently absorb light in the visible range and inject the photo-generated electrons into the carbon nanotube. Similar studies have been performed in C60-CdSe composites made by conventional means (A. Biebersdorf, R. Dietmuller, A. S. Susha, A. L. Rogach, S. K. Poznyak, D. V. Talapin, H. Weller, T. A. Klar, J. Feldmann, Nano Lett. 6, 1559 (2006); Hyunju Lee, Sang Won Yoon, Eun Joo Kim, and Jeunghee Park, Nano Lett. Vol. 7, No. 3, 778-784, 2007).

The nanoparticles in one example of the invention are synthesized following a hot-injection method similar to the one introduced by Peng et al. (L. Qu, X. Peng, J. Am. Chem. Soc. 124, 2049 (2002)). In the procedure followed in the invention herein cadmium oxide, CdO is dissolved in octadecylphosphonic acid (ODPA) and trioctylphosphinoxide (TOPO) are mixed in solution. The reaction takes place under nitrogen and stirring (between 100 rpm and 500 rpm); the temperature is increased to approximately 300° C. in order to dissolve the CdO into the ODPA. The TOPO is merely the reaction medium in this case. In this example, a metallic oxide entity is used as a source of the cadmium. However, organometallic precursors such as dimethyl cadmium can also be used as the source of cadmium. More generally it is believed that the invention works for other metal oxide or organometallic precursors. The ODPA is used as a ligand to complex the cadmium source. It is known also that tetradecylphosphonic acid (TDPA) can also be used—as an example for shorter chain alkylphosphonic acid derivates). The purpose of these ligands is that they are donors of electrons to the metal (Cd) and thus forming a coordinative bond of interaction.

Once an optically clear solution was obtained from the brown solution, the temperature of the optically clear solution is reduced to approximately 70° C. (between 70 and 90° C.) and a carbon particle suspension, for example a suspension of SWCNTs or MWCNTS in 1,2-dichloroethane (DCE) is added to the optically clear solution. The DCE is removed by evaporation of the solution for about 5 minutes. Alternatively, e.g. graphene layers can be added directly without prior dispersion in DCE as solids adsorbed on a solid substrate (a small piece of a silicon wafer for example) once the solution solidifies (below 50° C.).

In a further aspect of the invention, the nanotubes can be added as adsorbed material on a Si substrate.

Once the DCE is removed, the temperature is increased again to a range between 245° C. and 265° C. and pure elemental selenium dissolved in trioctylphosphine, TOP was injected into the optically clear solution. The reaction proceeds in a nitrogen atmosphere at a temperature between 245 and 255° C. for between two hours and one week. The CdSe nanoparticles are formed as CdSe nanorods in a few minutes. Since TOP can also dissolve Te, thus in a further aspect of the invention CdTe can be prepared according to the invention.

The reaction is stopped by cooling the mixture to 70° C., injecting approx 2 ml of toluene and then cooling to room temperature. The samples are purified by several cycles of shaking in toluene and centrifugation in order to prepare the grid for the TEM.

In another aspect of the invention, ZnO nanoparticles were attached to the carbon nanotubes by dissolving zinc acetate in an alcohol at 60° C. A suspension comprising SWCNT in methanol was made in an ultrasonic bath and added to the zinc acetate/alcohol solution at 60° C. Finally KOH dissolved in methanol was added drop-wise over a period of ten minutes.

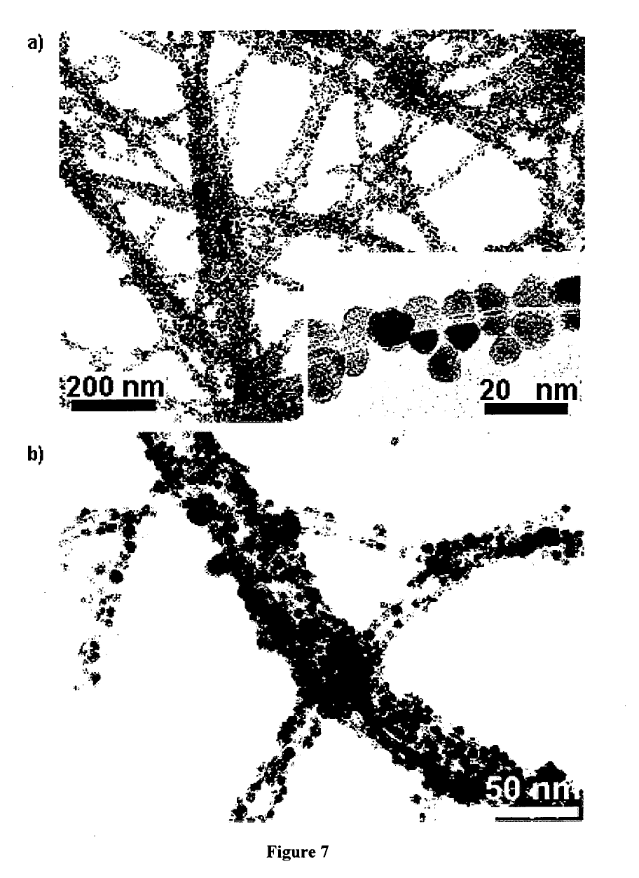

In a further aspect of the invention, InP nanoparticles attached to the carbon nanotubes was made by dissolving indium acetate or indium chloride in trimethylsilyl phosphine with a solvent of octadecene or trioctylphosphine and a stabilizer of trioctylphosphinoxide, myristic acid or dodecylamine. The carbon nanotubes were added to this solution. After a period of time, nanoparticles were observed on the surface of the carbon nanotubes as shown in FIG. 7.

In a further aspect of the invention, metallic alloy nanoparticle such as COₓPt_{y}, NiₓPt_{y} or FeₓPt are attached to non functionalised carbon surfaces.

Where the metallic alloy nanoparticles are COₓPt_{y}; the reaction was conditioned in vacuum at 80° C. for 1 hour before nucleation, in order to remove the possible traces of water from the reactants.

Subsequently the carbon nanotubes (CNTs), the ligands (oleylamine or oleylamine and oleic acid), the reducing agent (1,2-hexadecanediol) and the cobalt-precursor in the case of cobalt dichloride were heated at 200° C. for two hours in DPE (diphenylether) under a nitrogen atmosphere. After this time the platinum precursor (platinum(II)acetylacetonate) dissolved in 1,2-dichlorobenzene were injected amid vigorous stirring.

Three different sources of cobalt precursor were tried: cobalt(II) acetate (Co(Ac)₂), dicobalt octacarbonyl (CO₂(CO)₈) and cobalt(II) chloride hexahydrate (CoCl₂.6H₂O). In all instances platinum(II)-acetylacetonate (Pt(AcAc)₂) was the source of Pt. Two different ligands; oleic acid (OA) and oleylamine (OY) were employed in the process. MWCNTs and SWCNTs are dissolved in DPE.

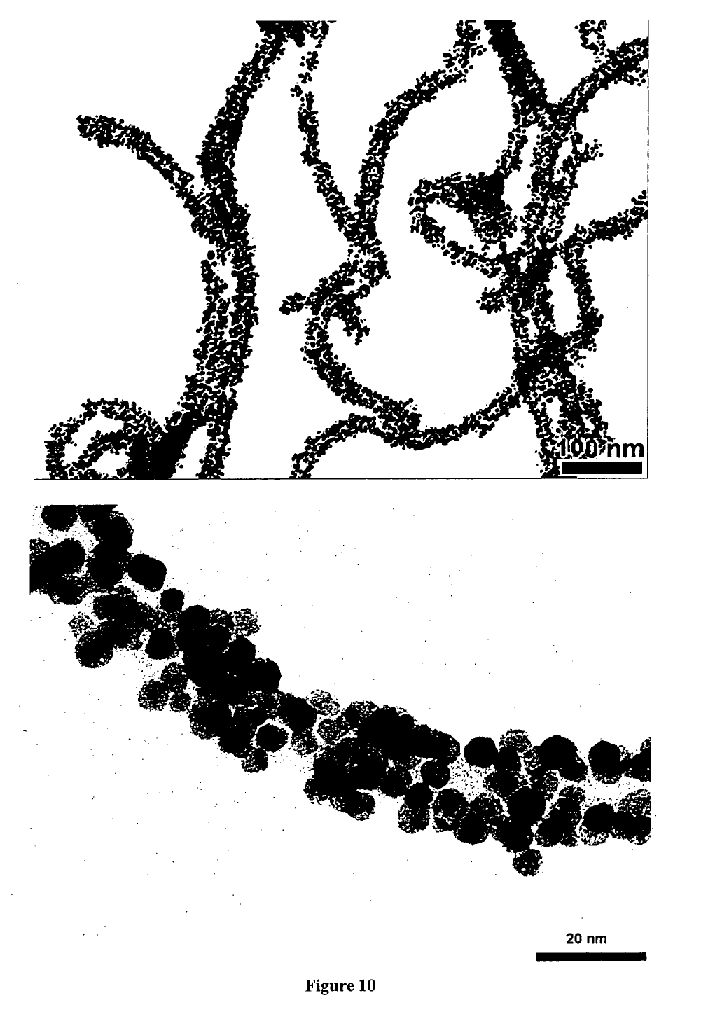

The best results are obtained from CO₂(CO)₈ with particles containing 5-10% cobalt. The particles are monodisperse and exhibit good coverage. In the case of CoCl₂.6H₂O the tubes are covered with spherical CoPt₃ particles. In this aspect the particles are in a stoichiometric ratio of Co=1/Pt=3 as depicted by FIG. 10.

FIG. 10 shows in the top half CoPt nanoparticles obtained by using CO₂(CO)₈ as a Co precursor and in the bottom half using CoCl₂.6H₂O as a Co precursor. In the top Figure the nanoparticles are Pt rich while in the bottom Figure they have a stoichiometry of ⅓

In this aspect of the invention the amount of ligand influences the composition of the alloy as well as the coverage on the carbon surface. To obtain the optimum results in terms of coverage and homogeneity of the particles it is required:

For platinum rich particles (5-10% Co) CO₂(CO)₈ was used as cobalt precursor:

### a) For MWCNT 0.05 ml OY+2 ml OA

Reaction time: from 10 minutes to 20 hours

### Quantity CNT=1 to 10 mg CNT/run.

### b) For SWCNT 0.05 ml OY+2 ml OA

Reaction time: from 10 minutes to 20 hours

### Quantity CNT=1 to 10 mg MWCNTt/run.

For CoPt₃ particles with the composition (1:3) CoCl₂.6H₂O was used as source of cobalt:

### a) For MWCNT 0.05 ml OY

Reaction time: from 10 minutes to 20 hours.

### Quantity CNT=1 to 10 mg CNT/run

### b) For SWCNT 0.05 ml OY

Reaction time: from 10 minutes to 20 hours.

### Quantity CNT=1 to 10 mg CNT/run

Without OA the manufacture proceeds to obtain CoPt₃ in a stoichiometric ratio (1:3). A deviation from the stoichiometry 1:3 is observed upon increasing the amount of OA. This gives rise to controlling the stoichiometry of the metal alloy nanoparticle composition by controlling the amount of ligand present in the mixture.

In this aspect of the invention the MWCNT are observed as being more reactive than the SWCNT. This means that compared to CdSe the same interaction is not observed. The cobalt platinum nanoparticles are attached by electrostatic interactions. Thus, the higher surface area of the MWCNTs compared to that of the SWCNTs favours the attachment of the metal alloy nanoparticles.

In a further aspect of the present invention where the metallic alloy nanoparticles are NiₓPt_{y}; the reaction was conditioned in vacuum at 80° C. for 1 hour before nucleation in order to remove possible traces of water from the reactants.

Subsequently the carbon nanotubes (CNTs), the ligands (oleylamine or oleylamine and oleic acid), the reducing agent (1,2-hexadecanediol) and the nickel (II)-acetate, Ni(Ac)₂ were heated at 200° C. for two hours in DPE (diphenylether) under a nitrogen atmosphere. After this time the platinum precursor (platinum(II)-acetylacetonate) dissolved in 1,2-dichlorobenzene were injected amid vigorous stirring.

Two different sources of the nickel precursor were utilised: nickel(II) acetate, Ni(Ac)₂) and bis(triphenlyphosphine)nickel dicarbonyl. In all instances platinum(II)-acetylacetonate (Pt(AcAc)₂) was the source of Pt. Two different ligands; oleic acid (OA) and oleylamine (OY) were employed in the process. The MWCNTs and the SWCNTs are dissolved in DPE.

The optimum results are obtained with Ni(Ac)₂ with as the particles are monodisperse and the carbon substrates exhibit good coverage.

FIG. 11 shows the NiPt nanoparticles attached to the MWCNTs

In this aspect of the invention the amount of the ligand was observed as well as and the influence of the ligand upon the composition of the alloy and as the coverage of the NiPt nanoparticles on the carbon surface. To obtain the optimum results in terms of coverage and homogeneity of the particles the following is required:

### a) For the MWCNT 0.05 ml OY

Reaction time: from 2 minutes to 20 hours

### Quantity CNT=1 to 10 mg CNT/run.

In this aspect of the invention, the presence of OA seems not to be important for the attachment of the NiPt to the carbon surface.

### b) For SWCNT 0.05 ml OY

Reaction time: from 10 minutes to 20 hours

### Quantity CNT=1 to 10 mg CNT.

Without OA we obtain alloyed nickel platinum particles in a composition from Ni₃₀Pt₇₀ to Ni₄₀Pt₆₀ depended of the amount of used nickelprecursor. As in the case of CoₓPt_{y} including higher quantities of OA yields alloys which are closer to only Pt as we increase the amount of OA. This gives the possibility of controlling the alloy composition by controlling the amount of ligands.

In a further aspect of the present invention where the metallic alloy nanoparticles are FeₓPt_{y}; the reaction was conditioned in vacuum at 80° C. for 1 hour before nucleation in order to remove possible traces of water from the reactants.

Subsequently the carbon nanotubes (CNTs), the ligands (oleylamine or oleylamine and oleic acid), the reducing agent (1,2-hexadecanediol) and Iron Pentacarbonyl were heated at 200° C. for two hours in DPE (diphenylether) under a nitrogen atmosphere. After this time the platinum precursor (Pt(AcAc)₂) was injected amid vigorous stirring. The results in terms of coverage and quality are similar to the previous systems of NiₓPt_{y} and COₓPt_{y}.

### EXAMPLES

### Example 1

### Manufacture of CdSe Nanoparticles

Cadmium oxide, CdO (0.025 g) ODPA (0.14 g) and trioctylphosphinoxide, TOPO (2.9 g) are mixed in a 25 ml three neck flask and degassed at 130° C. for one hour under vacuum. The temperature was increased to a range between 250° C. and 300° C. in order to dissolve the CdO into the ODPA and form a brown solution. The reaction took place under nitrogen and stirring (between 100 and 500 rpm).

Once an optically clear solution was obtained from the brown solution, the temperature of the optically clear solution was reduced to a temperature between 70-90° C. and a 1-3 ml CNT solution of CNT from Nanocyl in 1,2-dichloroethane (DCE) from Merck was added to the optically clear solution. The DCE was removed by placing the solution in vacuum for about 5 minutes.

Once the DCE was removed, the temperature was increased again to between 245° C. and 265° C. and pure selenium dissolved in trioctylphosphine, TOP (0.42 ml, 1M) from Fluka was injected into the optically clear solution. The reaction proceeded in a nitrogen atmosphere at approximately 255° C. for between two hours and one week. The CdSe nanoparticles were initially formed as CdSe nanorods but later changed to a pyramidal shape.

The reaction is stopped by cooling the mixture to 70° C., injecting approx 2 ml of toluene and then cooling to room temperature. The samples are cleaned by several cycles of shaking in toluene and centrifugation in order to prepare the grid for the transmission electron microscopy (TEM).

Different types of CNTs were used: single-wall CNTs (SWCNTs) produced by the HiPCO method and CVD (Nanocyl), SWCNTs grown by laser ablation, as well as multi-wall CNTs (MWCNTs) obtained by means of CVD (Baytubes).

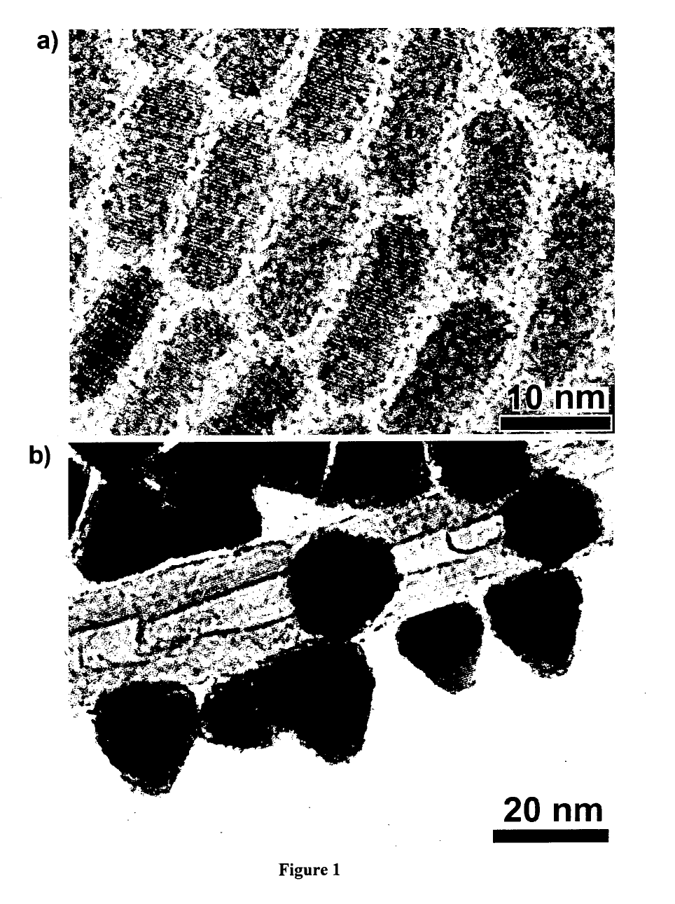

In a comparative experiment, the same method was repeated except that no CNTs were added to the reaction mixture. FIG. 1a shows a (TEM) image of CdSe NPs obtained without the use of CNTs after 48 hours and FIG. 1b shows a detail of pyramidal CdSe particles attached to the carbon system obtained after 48 hours of reaction in the presence of the MWCNTs. This demonstrates the effect that the CNTs have on the change of morphology of the system.

A dense coverage of sidewalls of both the SWCNTs and the MWCNTs with NPs was observed compared with the coverage obtained by means of methods involving surface oxidation on the carbon lattice. W. Ostwald, Z. Phys. Chem. 34, 495 (1900); Ostwald, W. Z. Phys. Chem. 37, 385 (1901). According to the TEM inspections many NP are closely positioned (atomically) on the sidewalls of the CNTs and a dense NP coverage is obtained on the sidewalls of the CNTs. This fact points to a close interaction of the NP with the surface of the sidewall of the CNT and not to a nucleation on defects sites on the surface of the sidewall of the CNT.

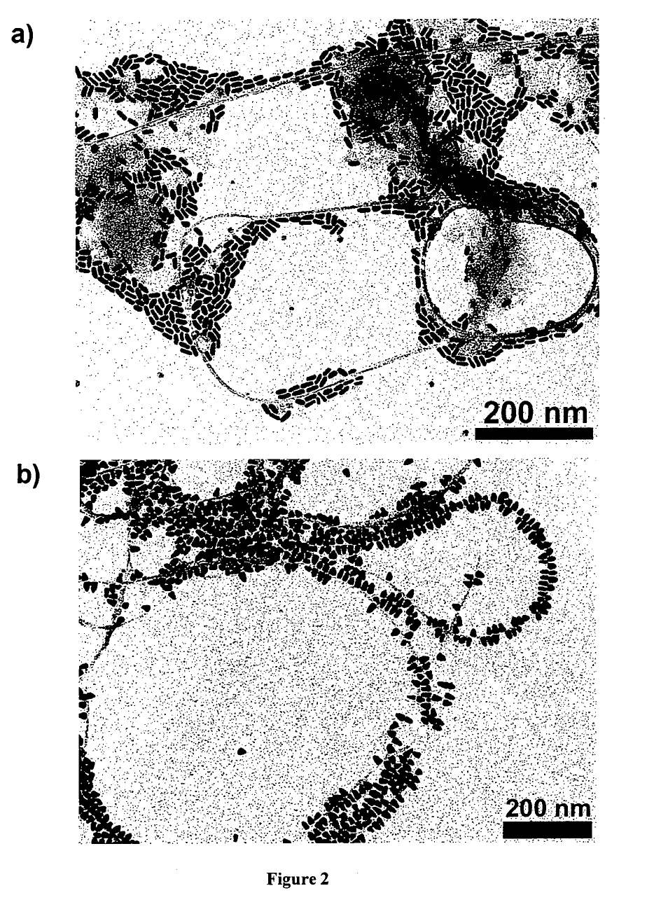

The evolution of the growth of the nanoparticles was followed. It was observed that in early stages of the growth of the nanoparticles (FIG. 2a) no significant variations in the growth of the nanoparticles can be observed with regard to the synthesis in absence of the CNTs. It should be noted that convective forces during preparation of a grid for the TEM lead to images in which the nanoparticles particles are placed together with CNT. This happens because during the preparation of the grid for the TEM a drop of the nanoparticles-carbon composites in toluene are dried on the surface of the grid. The toluene solvent evaporates and during the evaporation process, there are convective forces that tend to bring the nanoparticles together and eventually drive the nanoparticles and arrange the nanoparticles close to the nanotubes.

However, higher magnification images (not shown) point to a non specific interaction between the CdSe nanorods and the CNTs with a distance of about 2 nm between them. After periods of time that depend on the type of the CNT, i.e. SWCNT or MWCNT and the amount of the CNT, changes in the shape and the attachment of the nanoparticles are apparent (FIG. 2b). In this case, no distance between the CdSe and the carbon surface is apparent. The CdSe nanoparticles undergo a morphology change from a rod-like shape to pyramidal-shaped particles with a size ranging from 10 to 20 nm (measured along c-axis). It was noted that nanoparticles not attached to the surface of the CNTs possess the pyramidal shape as well. It was observed that the morphology change evolves faster in the presence of the SWCNT comparing with the MWCNT. This was attributed to a lower reactivity of the MWCNTs compared to the SWCNT. This relies on the small radius of curvature in the graphitic structure of the SWCNTs (compared to the MWNTs) which facilitates the interaction with the surface of the SWCNT.

It is known from Z. Adam Peng and Xiaogang Peng, J. Am. Chem. Soc. 2001, 123, 1389-1395 that the temporal shape evolution of the CdSe nanorods under the described experimental conditions (in the absence of the CNT) occurs in three different stages. The CdSe nanorods grow in a diffusion-controlled regime, a scenario where monomers migrate into the diffusion sphere of the nanoparticles and are mainly consumed by the facets perpendicular to the c-axis (1D-growth). When the synthesis proceeds for longer times, under 3D growth and 1D-2D ripening stages, the nanoparticles can eventually evolve to a more rounded shape. This fact was observed in the comparative studies for the CdSe nanorods when the reaction without the CNTs proceeds for longer times (i.e., 48 hours) as shown in FIG. 1a (L. Manna, E. C. Scher, A. P. Alivisatos, J. Am. Chem. Soc. 122, 12700 (2000)). L. Qu, X. Peng, J. Am. Chem. Soc. 124, 2049 (2002). The pyramidal shape nanoparticles are not formed within 28 hours in the absence of the CNTs. Further experiments by the inventors suggested that no shape transformation happened within 68 hours.

Previous studies have demonstrated a formation of pyramidal-shaped CdS NPs in an under stoichiometric sulphur/cadmium medium (J. Phys. Chem. B 2006, 110, 9448-9451). Moreover, with extra injections of both Cd and Se precursor, a similar morphological transformation from a rod shape to a pyramid shape has been recently reported for CdSe nanoparticles (P. Sreekumari Nair, Karolina P. Fritz, and Gregory D. Scholes, Small 2007, 3, No. 3, 481-487). In that work, the replacement of TDPA ligands for more labile ligands (such as acetate) promoted a shape transformation from the rod shape to pyramidal shape with pyramidal base particles due to energetic considerations. In contrast, in the invention, no extra cadmium or selenium sources are added in order to promote the further growth with shape evolution. In this invention the addition of CNT promotes a similar transformation and attachment to the carbon lattice.

Several control experiments were carried out in order to clarify the process and to study the role of each reactant in this system. It was ascertained that the shape evolution, as supported by previous work (P. Sreekumari Nair, Karolina P. Fritz, and Gregory D. Scholes, Small 2007, 3, No. 3, 481-487) is related with the ODPA ligands that cap the NPs surface.

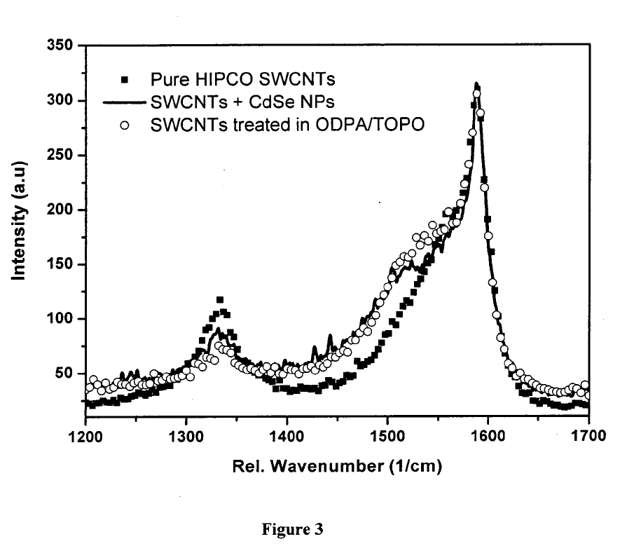

FIG. 3 displays the Raman response of pure SWCNTs before the synthesis and that of the sample shown in FIG. 2b. Additionally, a spectrum of a blank sample is shown for which the carbon nanotubes were treated in a mixture of ODPA/TOPO at 245° C., but in absence of both cadmium and selenium sources. Most striking is the similarity of the D peak intensities around 1330 cm⁻¹, which are attributed to sp³ carbon, for all three samples. The slightly larger signal of the pure carbon nanotubes is probably due to carbon contamination which has been removed during the chemical treatment of the other samples. These findings evidence that the carbon lattice is neither oxidized (sp³ hybridised) by the treatment with ODPA/TOPO mixtures nor during the nanoparticle evolution and attachment. Thus, the nanoparticles must be bound in a non-covalent manner to the nanotubes. Furthermore, one can see a broadening of the double G peak around 1600 cm⁻¹. This peak is attributed to carbon in the sp². state and similar broadening effects have been observed for metallic nanotubes and were interpreted as plasmon resonances.

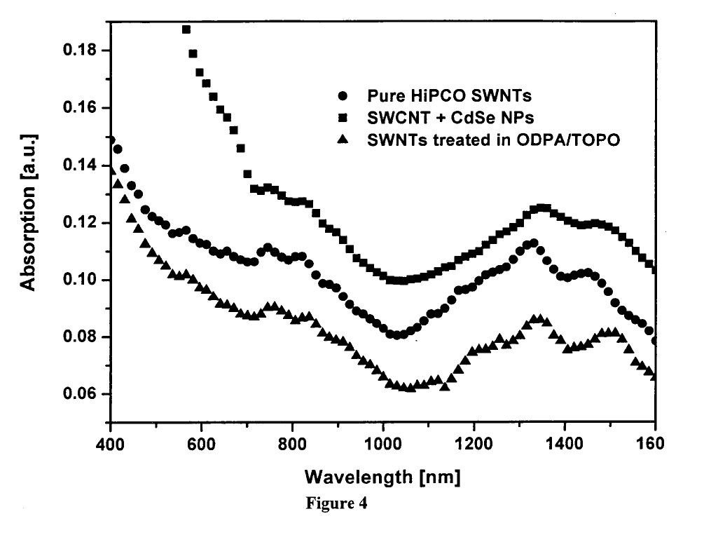

Semi-conducting nanotubes displays electronic transitions in different regions, namely between 800 and 1600 nm associated with the first dipole active excitation (E11) and between 600 and 800 nm associated with the second dipole active excitation (E22) (Kataura, H.; Kumazawa, Y.; Maniwa, Y.; Umezu, I.; Suzuki, S.; Ohtsuka, Y.; Achiba, Y. Synth. Met. 1999, 103, 2555; Spataru, C. D.; Ismail-Beigi, S.; Benedict, L. X.; Louie, S. G. Phys. Rev. Lett. 2004, 92, 077402 and Perebeinos, V.; Tersoff, J.; Avouris, P. Phys. Rev. Lett. 2004, 92, 257402). E11 transitions in metallic nanotubes bear absorption peaks between 400 and 600 nm. Optical absorption measurements on pure HiPCO SWCNTs, on the blank sample consisting of SWCNTs treated in a mixture ODPA/TOPO, and the SWCNT-CdSe NP composites exhibited in FIG. 2b are shown in FIG. 4. A comparison of the spectra does not show a significant deviation of the treated nanotubes compared to the pristine ones, neither in peak intensities nor in spectral shifts. This indicates that the interaction of the NPs is not covalent. A covalent attachment would lead to a drastic reduction or disappearance of the signal. The spectrum of the composite shows additionally the absorption edge of the semi-conducting CdSe NPs at 670 nm.

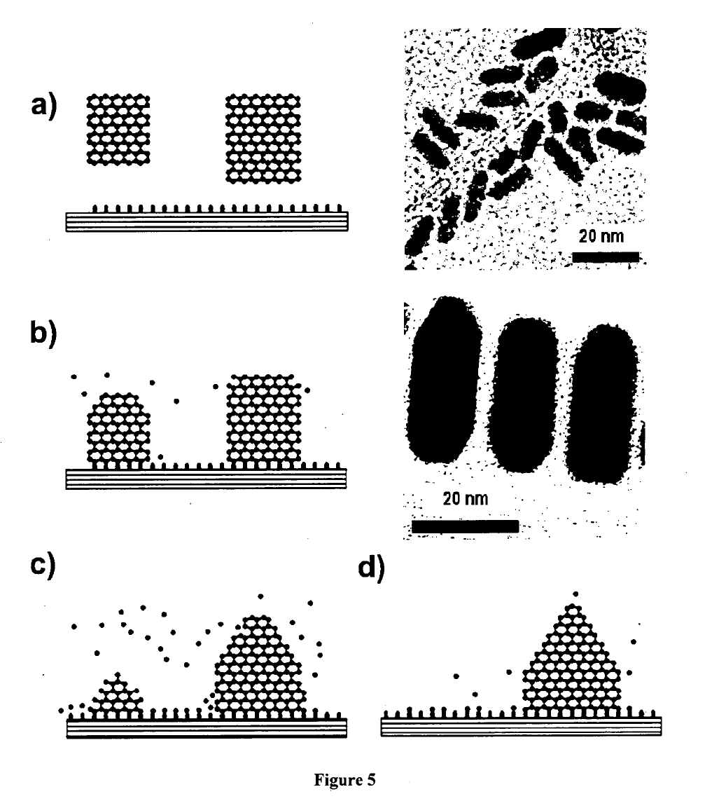

FIG. 5 illustrates the proposed mechanism for CdSe CNTs' interaction and further morphological transformation. In first stages of the reaction (a) the CdSe nanoparticles in the shape of nanorods are formed and remain in solution capped with ODPA and TOP as in the absence of CNTs (L. Qu, X. Peng, J. Am. Chem. Soc. 124, 2049 (2002), whereas the CNTs can be eventually surrounded by the organic ligands. The attachment of the nanorods is understood in terms of a ligand exchange of ODPA from the nanorod's Cd sites against the carbon nanotubes. Since there is no evidence of sp^{a} hybridisation of the carbon lattice, we propose that nanoparticle attachment is based on a non-covalent bond formed by an interaction of the filled CNT's π-orbitals with the empty conduction band states formed by Cd orbitals. Thus, the attachment of the NPs on CNTs is an analogue to coordinative bonds in complex chemistry on the nanoscale. It also implies that CNTs can be treated like coordinating ligands during nanoparticle synthesis opening novel concepts in nanochemistry. This model also readily explains the preferential orientation of the nanorods with their c-axis perpendicular to the nanotubes' surface, since in this orientation the purely Cd containing 00-2 lattice plane may be exposed to the CNT's π-system.

The shape transformation (b) starts with an etching process of ODPA which was also shown in control experiments without carbon nanotubes. This etching process should lead primarily to a Cd release and thus to Se rich surfaces, which the nanoparticles can provide by forming {10-1} lattice planes. The formation of these lattice planes is in agreement with the angle of approximately 30° measured in the TEM images between the {10-1} planes and c-axis of the formed pyramids. The nanoparticles will also slowly release Se in order to maintain the proper stoichiometry(c). However Cd etching should be faster and thus Se rich surfaces should terminate the nanoparticles under dynamic etching and Ostwald ripening conditions (d). Since the CNTs have a strong affinity to Cd the released Cd-ODPA species should be enriched and easily diffuse at the nanotubes surface to the neighboring particles. This diffusion of Cd monomers on the nanotube's surface and growing of facets with low chemical potential (big particles) leads to the dissolution of some nanoparticles and the growing of some others, following the classic concept of Ostwald ripening. This explanation is consistent with samples treated for 1 week under the mentioned experimental conditions in which a wider size distribution of nanoparticles attached to the carbon lattice is apparent. Furthermore, it was observed that pyramidal shaped particles were also found not only in contact to the nanotubes but also in solution. This fact suggests a mechanism of attachment and de-attachment from the carbon lattice. The enrichment step of Cd at the nanotubes's surface is the difference to processes occurring in homogeneous solution. The shape transformations after one week of Ostwald ripening implies that some lateral mobility of the atomic constituents of the nanoparticles at the CNT's surface must be possible. As determined by high resolution-TEM and selected area electron diffraction (SAED) patterns, the crystal lattice in the pyramidal CdSe NPs remains hexagonal after the transformation.

### Example 2

### Use of C60

Experiments with the C60 allotrope of carbon (buckminsterfullerene) yield a similar transformation of the shape of initially formed CdSe nanorods into pyramidal configurations. However, the final size distribution of the NPs is higher than in the case with the use of CNTs. This is due to the fact that C60 tends to form Van der Waals crystals with irregular shape.

### Example 3

### Manufacture of ZnO Nanoparticles

A solution was prepared by dissolving 1.5 g zinc acetate (from Aldrich) in 12 ml methanol (from Merck) at 60° C. A suspension comprising 0.3 mg SWCNT (or MWCNT) in 2 ml methanol was made in an ultrasonic bath and added to the zinc acetate/methanol solution at 60° C. Finally 300 mg KOH (from Aldrich) dissolved in 3 ml methanol (from Merck) was added drop-wise over a period of ten minutes. In early stages of the reaction the ZnO nanoparticles were formed as dots. The nanodots evolved into nanorods and after about 24 hours the ZnO nanoparticles are in the form of nanorods.

### Example 4

### Manufacture of ZnO Nanoparticles

The method was followed as in Example 4, except that butanol (from Merck) was used instead of methanol and that only 760 mg of zinc acetate from Aldrich was dissolved in 12 ml butanol. Furthermore the reaction was conducted at a temperature of 110° C.

### Example 5

### Manufacture of ZnO Nanoparticles

The method was followed as in Example 4, except that 2-phenylethanol from Merck was used instead of methanol and that only 266 mg of zinc acetate from Aldrich was dissolved in 12 ml 2-phenylethanol. Furthermore it was noted that the amount of nanotubes can be increased easily to 6 mg (SWCNT or MWCNT). In this method, the addition of 0.4 ml of oleic acid improves the shape and monodispersity of the particles as well as improves the coverage of the nanoparticles on the carbon surface.

The results with the manufacture of the ZnO nanoparticles are that the nanoparticles attach as well to the nanotubes but, the nanoparticles do not apparently change the shape. The nanoparticles produced with methanol (Example 4) are rod-like and in the presence of nanotubes the nanoparticles attach to the carbon nanotubes. If butanol is used as in Example 5, then the nanoparticles are not formed rod-like but are formed with a pyramidal shape, as in the case of CdSe (Example 1) and the nanoparticles attach to the surface of the carbon nanotubes. Furthermore it has been observed that when 2-phenylethanol is used with oleic acid, optimum results in terms of nanoparticle quality and attachment to the carbon surface is observed.

### Example 6

### Use of Amorphous Carbon

The procedure of Example 1 was repeated with active carbon from Merck. The active carbon is a combination of both amorphous carbon and crystalline carbon. Nanoparticles were attached to the surface of the active carbon. See the example of the graphene layers.

### Example 7

### Manufacture of InP Nanoparticles

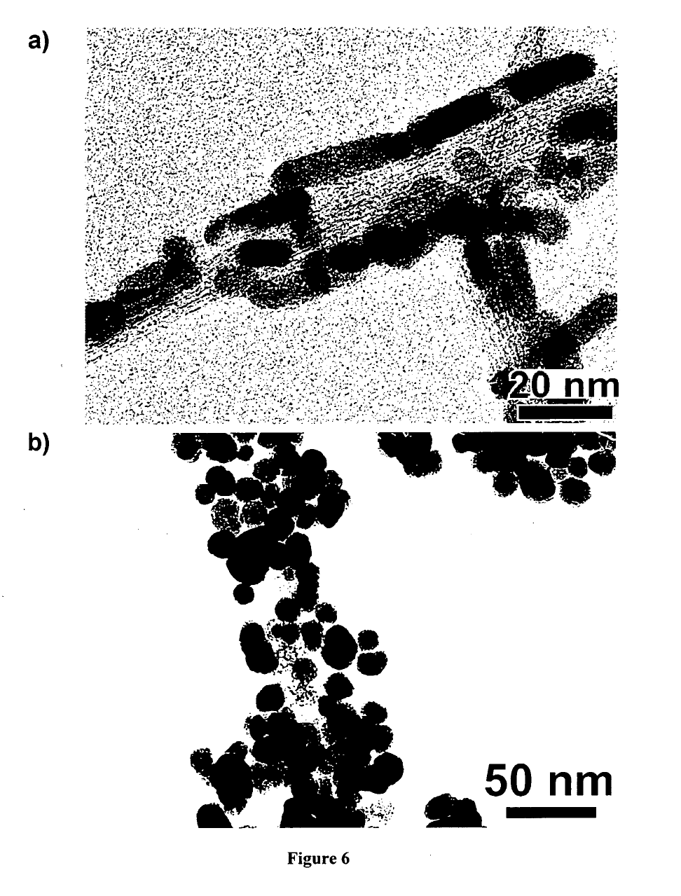

Three different approaches were tried in the InP-carbon nanotubes systems which yielded basically the same result, i.e., an attachment of the particles to the carbon nanotubes (see FIG. 6). No transformation of the shape of the nanoparticles was observed. These reactions were carried out in a nitrogen atmosphere.

### Example 8

### Manufacture of COₓPt_{y} Nanoparticles

The reaction mixture is initially conditioned in vacuum at 80° C. for 1 hour before nucleation in order to remove the possible traces of water from the reactants.

Subsequently the carbon nanotubes (CNTs), the ligands (oleylamine or oleylamine and oleic acid), the reducing agent (1,2-hexadecanediol) and the cobalt-precursor in the case of cobalt dichloride were heated at 200° C. for two hours in DPE (diphenylether) under a nitrogen atmosphere. After this time the platinum precursor (platinum(II)-acetylacetonate) was dissolved in 1,2-dichlorobenzene were injected amid vigorous stirring.

Three different sources of cobalt precursor were utilised: cobalt(II) acetate (Co(Ac)₂), dicobalt octacarbonyl (CO₂(CO)₈) and cobalt(II) chloride hexahydrate (CoCl₂.6H₂O). In all instances platinum(II)-acetylacetonate (Pt(AcAc)₂) was the source of Pt. Two different ligands; oleic acid (OA) and oleylamine (OY) were employed in the manufacture. MWCNTs and SWCNTs are dissolved in DPE.

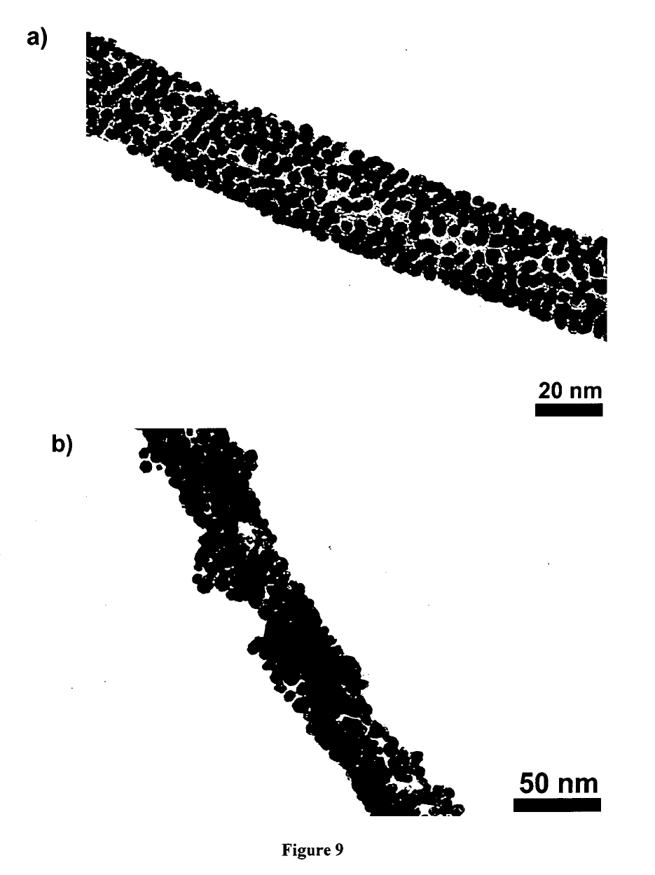

The best results were are obtained with CO₂(CO)₈ with the particles containing 5-10% cobalt. The particles are monodisperse and exhibit good coverage. In the case of CoCl₂.6H₂O the nanotubes are covered with spherical CoPt₃ particles. In this aspect the nanoparticles are stoichiometric Co=1 Pt=3 as depicted by FIG. 9.

FIG. 9 shows in the top half the CoPt nanoparticles obtained by using CO₂(CO)₈ as a Co precursor and in the bottom half using CoCl₂.6H₂O as a Co precursor. In the top Figure the nanoparticles are Pt rich while in the bottom Figure they have stoichiometry ⅓

### Example 10

### Manufacture of NiₓPt_{y} Nanoparticles

The reaction mixture is initially conditioned in vacuum at 80° C. for 1 hour before nucleation in order to remove the possible traces of water from the reactants.

Subsequently the carbon nanotubes (CNTs), the ligands (oleylamine or oleylamine and oleic acid), the reducing agent (1,2-hexadecanediol) and the nickel-precursor were heated at 200° C. for two hours in DPE (diphenylether) under a nitrogen atmosphere. After this time the platinum precursor (platinum(II)-acetylacetonate) was dissolved in 1,2-dichlorobenzene were injected amid vigorous stirring.

Two different sources of nickel precursor were utilised: nickel(II)acetate (Ni(Ac)₂) and Bis(triphenlyphosphine) nickel dicarbonyle. In all instances platinum(II)-acetylacetonate (Pt(AcAc)₂) was the source of Pt. Two different ligands; oleic acid (OA) and oleylamine (OY) were employed in the manufacture. MWCNTs and SWCNTs are dissolved in DPE.

FIG. 10 shows NiPt nanoparticles attached to MWCNTs.

InAc₃+P(SiMe₃)→InP Reaction 1.

Solvent: ODE (octadecene), Stabilizer: Myristic acid (MA).

1 mmol InAc₃ (Indium Acetate) from Alfa Aesar, 0.5 mmol P(SiMe₃)₃ (trimethylsilyl phosphine) from Acros, 3 mmol MA from Aldrich, 24 ml ODE (octadecene) from Aldrich and (single-wall carbon nanotubes) SWCNT from Nanocyl in DCE. Hot injection at 300° C. and allowed to grow at 270° C.

InCl₃+P(SiMe₃)→InP Reaction 2

Solvent: TOP (trioctylphosphine), Stabilizer: TOPO (trioctylphosphinoxide)

0.75 mmol InCl₃ (indium chloride) from Alfa Aesar, 0.75 mmol P(SiMe₃)₃ (trimethylsilyl phosphine) from Acros, 6.75 g TOP (trioctylphosphine) from Fluka, TOPO 0.75 g from Alfa Aesar and SWCNT from Nanocyl in DCE. Hot injection at 300° C. and allowed to grow at 270° C.

InCl₃+P(SiMe₃)→InP Reaction 3

Solvent: TOP (trioctylphosphine), Stabilizer: DDA (dodecylamine)

1.5 mmol InCl₃ (indium chloride) from Alfa Aesar, 1.5 mmol P(SiMe₃)₃ (trimethylsilyl phosphine) from Acros, 5 ml TOP (trioctylphosphine) from Fluka, 12 g DDA (dodecylamine) from Merck and SWCNT from Nanocyl in DCE at 240° C.

1. The combination of at least one substantially unfunctionalised carbon surface and at least one nanoparticle, wherein the at least one nanoparticle is directly attached to the substantially unfunctionalised carbon surface.

2-32. (canceled)
